(19) United States
(12) Patent Application Publication
(10) Pub. No.: US 2015/0027513 A1
(43) Pub. Date: Jan. 29, 2015

(54) SEMICONDUCTOR SUBSTRATE FOR A PHOTOVOLTAIC POWER MODULE

(71) Applicant: Solar Systems Pty Ltd, Abbotsford, Victoria (AU)

(72) Inventors: William Ring, High Bridge, NJ (US); Joel Goodrich, East Melbourne (AU); Zhen Mu, Wantirna (AU); Robert Musk, Kingston (GB)

(73) Assignee: Solar Systems Pty Ltd, Abbotsford, Victoria (AU)

(21) Appl. No.: 14/361,688

(22) PCT Filed: Nov. 21, 2012
(86) PCT No.: PCT/AU2012/001432

§ 371 Date: May 29, 2014

Related U.S. Application Data
(60) Provisional application No. 61/565,415, filed on Nov. 30, 2011.

(51) Int. Cl. H01L 31/0352; H01L 31/042; H01L 31/048; H01L 31/18; H01L 31/052

(52) U.S. Cl. CPC H01L 31/0352; H01L 31/18; H01L 31/052; H01L 31/0485; H01L 31/0428
USPC 136/249; 438/67; 136/261; 136/259

(57) ABSTRACT

A semiconductor substrate and a photovoltaic power module incorporating the semiconductor substrate. The substrate includes one or more bypass diodes formed integrally in the semiconductor substrate, each bypass diode corresponding to a respective one or more photovoltaic cells, and metallised zones being electrically and thermally coupled to the bypass diodes. The substrate enables photovoltaic cells to be placed close together, and has low thermal resistance. Methods of manufacturing the substrate and module are provided.

### FIELD OF THE INVENTION

The present invention relates to semiconductor substrates for photovoltaic power modules, photovoltaic power modules and methods for manufacturing such semiconductor substrates and photovoltaic power modules. The present invention has applicability in concentrated solar power systems, but is not to be taken to be limited to this example.

### BACKGROUND OF THE INVENTION

A concentrated solar power system includes a receiver and a concentrator. The concentrator reflects light incident on a relatively large surface area to a relatively small surface area of the receiver. The concentrator may take many different forms. For example, the concentrator may be a dish reflector that includes a parabolic array of mirrors that reflect light towards the receiver. The concentrator may alternatively be a heliostat reflector that includes a field of independently movable flat mirrors.

The receiver includes a plurality of photovoltaic power modules, each module including a dense array of photovoltaic cells. The receiver also includes an electrical circuit for transferring the electrical energy output of the photovoltaic cells and an inverter to convert the DC output of the photovoltaic cells to AC.

A typical photovoltaic cell is a semiconductor device that converts solar energy to electrical energy by the photovoltaic effect. Photons from sunlight having an energy that matches or exceeds the bandgap of the semiconductor are absorbed, knocking loose electrons that may then flow through an external current path to produce electricity. Multi junction solar cells have multiple layers of semiconductor materials with decreasing bandgaps. The upper layers absorb high energy photons and transmit lower energy photons to be absorbed by the lower layers. Multi junction cells thus convert sunlight to electricity more efficiently than single junction cells.

Bypass diodes are connected in parallel to one or more photovoltaic cells connected in series to prevent reverse voltage across the corresponding cells when the cells have a reduced power output due to poor illumination or a malfunction. This prevents damage or destruction of the affected cells by hot spot heating and enables the rest of the photovoltaic cells in the module to continue operating.

Bypass diodes are typically located between adjacent cells. However, this requires gaps between the cells to make room for the diodes. In a concentrated photovoltaic system, where concentrated light is directed at a receiver, this results in energy wastage as the concentrated light falling within gaps between adjacent cells in the dense array is not absorbed and converted to electrical energy.

It would be desirable to provide a photovoltaic power module that addresses one or more of the limitations described above or provides an alternative to existing photovoltaic power modules.

The above discussion of background art is included to explain the context of the present invention. It is not to be taken as an admission that any of the documents or other material referred to was published, known or part of the common general knowledge at the priority date of any one of the claims of this specification.

### SUMMARY OF THE INVENTION

The present invention provides a photovoltaic power module including one or more photovoltaic cells for converting photons to electrical energy, a semiconductor substrate including one or more bypass diodes formed integrally in the semiconductor substrate, each bypass diode corresponding to a respective one or more of the photovoltaic cells, and metallised zones constituting a circuit and provided between the substrate and the photovoltaic cells, the metallised zones being electrically and thermally coupled to the photovoltaic cells and the bypass diodes.

The present invention further provides a semiconductor substrate including one or more bypass diodes formed integrally in the semiconductor substrate, each bypass diode corresponding to a respective one or more photovoltaic cells, and metallised zones being electrically and thermally coupled to the bypass diodes.

By integrating one or more bypass diodes into the semiconductor substrate, the invention enables the photovoltaic cells to be placed closer together than arrangements with bypass diodes located between adjacent cells. This may increase the efficiency of the photovoltaic power module, as light that would otherwise be wasted may be converted to electrical energy. The present invention provides particular advantages in concentrated solar power systems, where concentrated light is directed towards the receiver and power modules. However, it is to be understood that the invention is not to be taken to be limited to this application, and has applicability to other solar power generation systems.

Further, the applicant has found that the integration of one or more bypass diodes into the substrate provides a reduced thermal resistance compared to an arrangement with separately formed diodes located in recesses under the photovoltaic cells. Thermal energy may more easily dissipate through the substrate with integrated diodes.

In addition, forming the bypass diodes in the semiconductor substrate enables smaller diodes to be used. Where diodes are physically positioned, for example using a pick and place robot, the diode must be large enough to be physically handled. By contrast, a diode formed in the semiconductor substrate may be too small to be seen by eye, for example 0.005 mm or smaller. A small diode enables the series connection of more photovoltaic cells in a given area. More cells means a higher voltage and less current and therefore means less power lost to the series resistance of the substrate. The module voltage may be increased to the designed receiver voltage with all modules connected in parallel in the receiver. The output power of the receiver has been shown by modelling to increase when all the modules are parallel connected.

Thermal resistance is a problem with separately formed diodes, as the diode needs to have a gap around it for electrical insulation (this can either be left as an air gap or potted using an encapsulant). This low thermal conductive region results in an increase in thermal resistance. A stand alone diode is also more costly as it requires further packaging and processing both in terms of pick and place, attachment and also with wirebonding or some other electrical connection. An integrally formed diode may avoid these problems.

The semiconductor substrate may include a cell side surface and each bypass diode may include a first terminal and a second terminal, the first and second terminals being located on the cell side surface of the semiconductor substrate. By “terminal” of the diode, it is to be understood to mean an external surface of the positive or negative material of which the diode is composed. The cell side surface of the semiconductor substrate may be a smooth flat surface. Alternatively, the cell side surface may include islands where the bypass diodes are located. With the diode terminals located on the cell side surface, the metallised zones coupling the photovoltaic cells and bypass diodes may thus be deposited on the cell side surface, facilitating the manufacture and assembly of the module.

For each bypass diode, a junction on the cell side surface between the first terminal and second terminal may be located between two photovoltaic cells. This may facilitate connecting the first terminal with a first photovoltaic cell and the second terminal with a second photovoltaic cell via the metallised zones. The junction on the cell side surface may be an edge of a PN junction of the diode. Alternatively, each bypass diode may be located underneath a photovoltaic cell, and the metallised zones may extend through or on top of the substrate (with appropriate insulation), to connect the diodes across the cells.

The bypass diodes may have an interleaved or finger shaped design. For example the design may be similar to the shape of two interlocking combs, with one comb being a P-type region and the other comb being an N-type region. This design may increase the contact area between the P and N regions and hence may improve the diode's current carrying capacity.

For each bypass diode, a first metallised zone may at least partially overlie the first terminal and a second metallised zone may at least partially overlie the second terminal. The first metallised zone may at least partially underlie a first photovoltaic cell of the one or more photovoltaic cells and the second metallised zone may at least partially underlie a second photovoltaic cell of the one or more photovoltaic cells. The first metallised zone may thus provide a contact to both a cell terminal and a diode terminal. For example, one side of the metallised zone may provide a cell contact and the other side may provide a diode contact. Thus, the diodes need not be wirebonded to the metallised zones, simplifying the production process. This provides advantages over a standalone diode, which requires an extra processing step to electrically connect the diode. The integral diode does not need any other electrical connection. Metallisation may be done as a semiconductor processing step.

Integrated circuits (ICs) are less expensive than hybrid discrete circuits with the same number of components. The cost of placing and connecting a discrete bypass diode increases linearly with the number of diodes. In this example of integrated diodes the cost of 100 bypass diodes per circuit may be the same as the cost of one diode.

The photovoltaic power module may further include a shield associated with each bypass diode for reducing exposure of the bypass diode to photons. When a diode is exposed to photons, it becomes conductive, with the amount of current through the diode being proportional to the light falling on the diode. In a concentrated solar power system this may be problematic, as the light falling on the diode may be concentrated to e.g. 500 times the normal intensity of sunlight. This may result in a large loss of current, which may shunt across the photovoltaic cells.

The shield may overlie any exposed areas of silicon of the bypass diodes, including the first terminal, the second terminal and a junction on the cell side surface between the first terminal and second terminal. The shield may be opaque, such that it does not allow light to pass through. For example, each shield may be made of metal and the module may further include a dielectric material between each shield and its associated bypass diode. As the dielectric material may be transparent or translucent, the shield may overlie a larger area than the exposed silicon areas of the bypass diode in order to reduce the amount of light transmitting under the shield.

Examples of suitable dielectric material include silicon dioxide, silicon nitride or a polymer that is compatible with metal e.g. BCB (benzocyclobutene). Where the shield is metal, preferably the dielectric is non-conductive so that the associated bypass diode is not shorted by the metal shield.

It will be appreciated that the shield may be made of any other material that prevents the transmission of light. For example, a dielectric with a dye could be used. However, a metal shield is preferred because it reflects light, whereas a dielectric/dye combination absorbs light and thus heats up. For example, the shield may be made from gold, copper, aluminium or silver.

The photovoltaic cells may be connected in series and each photovoltaic cell apart from end photovoltaic cells in the series may have an associated metallised zone that underlies the photovoltaic cell and connects the photovoltaic cell to a first terminal of a bypass diode corresponding to the photovoltaic cell and to the second terminal of a bypass diode corresponding to an adjacent photovoltaic cell. The metallised zone may have a larger surface area than the footprint of its associated cell. This may allow for the maximum material tolerance of the cells and may ensure that the cells self-centre during reflow. The larger surface area of the metallised zone may also facilitate heat flow from the cell to the substrate. Making this pad too large, however, may have a negative impact on the array as this may accordingly lead to larger gaps between adjacent cells (cells can't bridge the pads).

Any directional terms used in this specification, for example “overlie”, “underlie”, “upper”, “lower”, “above”, “below” are to be understood to be describing the relative positions of parts of the product and not to be taken to limiting the orientation of the product. For example, if metallised zones overlie diode terminals when the module is oriented with its photon source facing surface directed vertically towards the sky, it is to be understood that the metallised zones continue to overlie the diode terminals even if the module is pointed at an angle to the vertical. It is also to be appreciated that these terms do not require, for example, the overlying part to be directly on top of the part it is overlying. Other layers may be between the overlying part and the part it is overlying.

The one or more photovoltaic cells may be single or multi junction cells, and may be electrically connected in series, parallel or a combination of series and parallel, as would be understood by the skilled addressee. The photovoltaic cells may be arranged in a two dimensional array, in abutting relationship on a curved substrate, on a multi-surface substrate such as a cube or in a linear dense array of cells.

The one or more bypass diodes may be PN diodes, schottky diodes or any other type of diode. Where the bypass diodes are PN diodes, the first and second terminals may be formed by doping the semiconductor substrate to form P-type and N-type regions respectively. Examples of n-type dopants include phosphorus, antimony, and arsenic. P-type dopants include boron (most common), aluminium, and gallium. Where the bypass diodes are schottky diodes, the first terminal of each bypass diode may include a schottky contact and the second terminal may include a N doped region. Appropriate materials for the shottky contact include aluminium/tantalum nitride (Al/TaN), gold, titanium and platinum. Many other materials may be used, as would be understood by the skilled addressee. Each bypass diode may correspond to a single photovoltaic cell, or a single bypass diode may correspond to multiple photovoltaic cells.

The semiconductor substrate may be a silicon substrate (e.g. a silicon on insulator substrate (SOI) or a conventional bulk silicon substrate), a gallium arsenide substrate, a geranium substrate or any other semiconductor substrate. A silicon substrate is preferred as it is currently the most developed, highest capability, lowest cost material for the substrate. Silicon is a widely used semiconductor and there are well established processes for forming components in silicon, for example using doping, etching and deposition. The semiconductor substrate may be manufactured using integrated circuit technology.

Where the semiconductor substrate is a silicon on insulator substrate, a bottom silicon layer of the SOI substrate may be highly doped. The silicon may thus be used as a conductor. For example, the bottom silicon layer may be a less than 2 mohm-cm, e.g. 0.001 ohm-cm, highly doped N+ substrate. The photovoltaic power module may further include vias in the bottom silicon layer connecting end photovoltaic cells in a series of connected photovoltaic cells to power pins on a back of the photovoltaic power module. The vias may enable current to flow to the power pins from a position on the module located away from the power pins.

The present invention also provides a method of manufacturing a photovoltaic power module including doping a semiconductor substrate to form one or more bypass diodes integrally in the semiconductor substrate, the semiconductor substrate including a cell side surface, wherein each bypass diode includes a first terminal and a second terminal, the first and second terminals being located on the cell side surface of the semiconductor substrate, depositing metallised zones to at least partially overlie a first terminal of a bypass diode and a second terminal of an adjacent bypass diode, and mounting one or more photovoltaic cells in electrical connection with the metallised zones.

As mentioned above, the semiconductor substrate may be a silicon on insulator (SOI) substrate. A SOI substrate includes two silicon wafers with an insulating layer such as silicon dioxide in between. In this case, the bypass diodes may be formed in the substrate as islands on the surface of a top silicon wafer. A SOI substrate allows a high standoff voltage across the substrate, which may be desirable due to the number of photovoltaic cells and bypass diodes connected in series.

The metallised zones may be formed of any metal or from layers of metal. For example, the metallised zones may include metal that is solderable and able to be wire bonded. For example, gold, copper or silver may be used. The photovoltaic cells may be coupled to the metallised zones by solder or conductive adhesive. The metallised zones may be formed on the bypass diodes by electron beam evaporation, vapour deposition, ion-beam sputtering or other thin film techniques.

The method may further include, after depositing the metallised zones, depositing a dielectric material to at least partially overlie each bypass diode, and depositing further metallised zones over the dielectric material, thus reducing exposure of the bypass diodes to photons. As mentioned above, shielding exposed silicon areas of the bypass diode may prevent the diodes from becoming conductive and shunting current through the photovoltaic cells.

After depositing the further metallised zones, the method may include depositing further dielectric material over the further metallised zones. The further dielectric material may prevent a wirebond connecting a top of the photovoltaic cell to a metallised zone from coming into contact with the metal shield.

Where the semiconductor substrate is a silicon on insulator substrate, the method may further include highly doping a bottom silicon layer of the silicon on insulator substrate. The bottom layer may thus become quite conductive. The method may further include etching channels to form vias in the bottom silicon layer, the vias connecting end photovoltaic cells in a series of connected photovoltaic cells to power pins on a back of the photovoltaic power module, and coating the channels with an insulator. Thus, vias with redistribution may be formed in the bottom silicon layer, simplifying the manufacturing method. The insulator may be silicon dioxide or any other appropriate insulator.

The present invention extends to a method of manufacturing a semiconductor substrate including doping a semiconductor substrate to form one or more bypass diodes integrally in the semiconductor substrate, the semiconductor substrate including a cell side surface, wherein each bypass diode includes a first terminal and a second terminal, the first and second terminals being located on the cell side surface of the semiconductor substrate, and depositing metallised zones to at least partially overlie a first terminal of a bypass diode and a second terminal of an adjacent bypass diode.

Integrating bypass diodes into a semiconductor substrate may be simpler and cheaper than, for example, integrating bypass diodes into a photovoltaic cell. Integration of a diode into a PV cell may require etching through the cell to isolate the diode from the cell. Also, the area of the cell taken by the diode may reduce the area of the cell that is available to generate electricity. Integrating a bypass diode into a PV cell may thus be a more expensive process that results in a cell with a decreased yield, when compared with integrating a bypass diode into a semiconductor substrate.

The method of manufacturing the semiconductor substrate may include any of the steps described above in relation to the method of manufacturing a photovoltaic power module. For example, the method may further include, after depositing the metallised zones, depositing a dielectric material to at least partially overlie each bypass diode, and depositing further metallised zones over the dielectric material, thus reducing exposure of the bypass diodes to photons.

Where the semiconductor substrate is a silicon on insulator substrate, the method may further include highly doping a bottom silicon layer of the silicon on insulator substrate, etching channels to form vias in the bottom silicon layer, and coating the channels with an insulator.

The semiconductor substrate may further include a heat sink formed integrally in the semiconductor substrate. For example, the heat sink may be formed using microelectromechanical systems (MEMS) technology, as would be understood by the skilled addressee. The heat sink may be built in layers of wafers which are stacked and etched individually using a photoresist pattern, and finally heated to a high temperature so that the wafers fuse together. For example, 3 or 4 layers of silicon wafer may be used. The heat sink may be formed as a separate substrate which may be bonded to the semiconductor substrate including the bypass diodes.

Forming the heat sink integrally with the substrate may provide advantages in facilitating thermal transfer from the photovoltaic cells through the module. Where a separate heat sink is attached to the substrate, the attachment means (e.g. solder) may add thermal resistance. Further, the solder may fail over time due to changes in temperature of the module when in use. Different materials for the substrate and heat sink attached together may create a coefficient of thermal expansions mismatch and this may lead to increased stress during attachment processing and with thermal cycling in operation. The integrally formed heat sink may contain microchannels, slots or posts of an appropriate form factor.

The semiconductor substrate may further include one or more power converters formed integrally in the semiconductor substrate. The semiconductor substrate may include a power converter per module, a power converter for each photovoltaic cell, or a power converter for one or more groups of series connected photovoltaic cells, for example located in an n×n array. The groups of cells need not be of the same size or number. The power converters may be formed in a separate semiconductor layer or stacked layers and bonded to the semiconductor substrate.

The power converter may be an inverter, for converting the DC output of the photovoltaic cells to AC, a DC-DC converter, for boosting the DC voltage output of the photovoltaic cells, a DC-DC converter connected to an inverter, or any other type of power converter. A system using an external inverter suffers from loss over the cables between the modules and the inverter. By integrating the inverter into the silicon substrate, these losses may be reduced and the power output of the module increased. The power converter may be formed using power switching devices such as MOSFETs and IGBTs, and other electronic components such as resistors, capacitors and inductors. These devices may be manufactured through silicon wafer processing. The power converter, for example may be formed on the back of the module, underneath the heat sink.

Where cells and modules are connected in parallel and use a common external inverter, large copper conductors are needed between the modules and the inverter. This adds cost to the system. Also, an unlit cell may limit the voltage and therefore power output by the system. Module or cell level power converters reduce the size of conductors needed, thus reducing the cost of the copper cabling, and reduce the impact of an unlit cell to those cells sharing the same power converter as the unlit cell.

Where cells and modules are connected in series and use a common external inverter, the current produced by the arrangement is limited by the current of the least lit cell. Module or cell level inverters reduce the number of cells or modules affected by a low light or shaded cell.

The applicant has found that the flux intensity of concentrated light falling on a photon source facing surface of a module differs across the surface. However, the flux intensity is similar in geometrical regions of the surface. The inclusion of a power converter for one or more groups of series connected photovoltaic cells, for example located in an n×n array, takes advantage of this similar flux intensity. If cells having a similar flux intensity share a common inverter, then less power is wasted by the current of the brightest cell being limited by the current of the least lit cell. For example, the group of cells may be 4 cells located in a 2×2 array or 9 cells located in a 3×3 array. The applicant has found that this grouping takes advantage of the flux distribution across the photon source facing surface. Alternatively, the group of cells may be in an n×m array, for example 6 cells in a 2×3 array. The grouping of cells may be individualised based on a measured flux distribution for the receiver.

Providing a power converter at the cell level or for groups of cells may also enable the tolerance of a concentrator to be relaxed. It may be difficult to properly align optical elements (e.g. mirrors) in the concentrator to achieve an even flux distribution across the multiple modules of a receiver. Aligning and accurately positioning the mirrors to track the sun may be an expensive procedure. Module/cell level power converters reduce the impact of flux distribution on the power output of the module, thus reducing the impact of accuracy in alignment of the optical elements of the concentrator.

The present invention also provides a photovoltaic power module including one or more photovoltaic cells for converting photons to electrical energy and a semiconductor substrate including one or more power converters formed integrally in the semiconductor substrate, each power converter corresponding to a respective one or more of the photovoltaic cells. By integrally forming components of the photovoltaic power module into a semiconductor substrate, advantages may be achieved in assembly, cost, efficiency and cooling of the module.

Other components of the photovoltaic power module may also be integrally formed in the substrate such as blocking diodes, temperature sensing devices, current sensing devices and/or a measurement circuit. These components may be formed using integrated circuit technology.

The substrate may also include through-silicon-vias—TSVs provide electrical connection between the two faces of the silicon substrate. If incorporated into the substrate, the TSVs may carry the power generated from the PV cells on the photon facing surface to the heatsink face of the substrate. Where a power converter is included in the substrate, the TSVs may connect the power converter to the cells.

As described above, the vias may conduct using the substrate material in the case of a silicon on insulator substrate with a highly doped bottom layer. Where a silicon substrate is used, the vias may be formed by etching a hole through the substrate, coating the sides of the hole with insulator and filling the hole with a conductor.

The module may further include one or more channels etched around the edge of the module and filled with an insulator, to allow a high stand off voltage across the substrate. These channels may, for example, provide edge isolation sufficient to meet industry requirements. Conveniently, the channels may be formed in the same processing steps as used to form vias in the substrate.

### BRIEF DESCRIPTION OF THE DRAWINGS

Embodiments of the present invention will now be described, by way of example only, with reference to the accompanying drawings. It is to be understood that the particularity of the drawings does not supersede the generality of the preceding description of the invention.

FIG. 1 is a perspective view of a system for generating electrical power from solar radiation.

FIG. 2 is a front view of a receiver of the system of FIG. 1.

FIG. 3 is an exploded side view of a photovoltaic power module according to an embodiment of the invention.

FIG. 4 is a partial side cross sectional view of the photovoltaic power module of FIG. 3.

FIG. 5 is schematic side cross sectional view of a PN diode structure.

FIG. 6 is a schematic side cross sectional view of a schottky diode structure.

FIG. 7 is a schematic plan view of a finger shaped diode design according to an embodiment of the invention.

FIG. 8 is a partial side cross sectional view of a photovoltaic power module with a silicon on insulator (SOI) substrate according to another embodiment of the invention.

FIG. 9 is a partial side cross sectional view of two photovoltaic power modules and bypass diodes with associated shields according to another embodiment of the invention.

FIG. 10 is a partial side cross sectional view showing a SOI substrate with an integrated bypass diode and vias.

FIG. 11 is a partial side cross sectional view of the substrate of FIG. 10 with a photovoltaic cell attached to the substrate.

FIG. 12 is a schematic plan view of a photovoltaic power module including a plurality of power converters for a plurality of groups of cells according to another embodiment of the invention.

FIG. 13 is a schematic plan view of a photovoltaic power module including a single power converter according to another embodiment of the invention.

### DETAILED DESCRIPTION

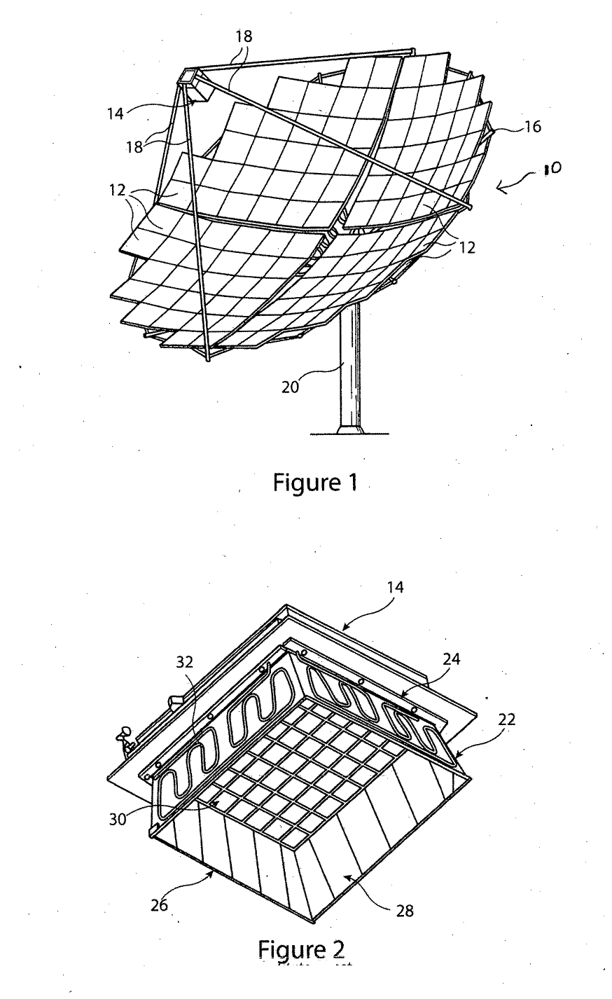

A concentrated solar power generating system 10 shown in FIG. 1 includes a concentrator 12 in the form of an array of mirrors that reflect solar radiation that is incident on the mirrors towards a receiver 14. The receiver 14 includes photovoltaic cells that convert reflected solar radiation into DC electrical energy. The receiver 14 also includes an electrical circuit (not shown) for the electrical energy output of the photovoltaic cells.

The concentrator 12 is mounted to a framework 16. A series of arms 18 extend from the framework 16 to the receiver 14 and locate the receiver as shown in FIG. 1. The system 10 further includes a support assembly 20 that supports the concentrator 12 and the receiver 14 in relation to a ground surface and for movement to track the sun; and a tracking system (not shown) that moves the concentrator 12 and the receiver 14 as required to track the sun. The receiver 14 also includes a coolant circuit which cools the receiver 14 with a coolant, preferably water, in order to maintain a safe operating temperature and to maximise the performance (including operating life) of the photovoltaic cells.

With reference to FIG. 2, the receiver 14 has a generally box-like structure. The receiver 14 also includes a solar flux modifier 22, which extends from a lower wall 24 of the box-like structure. The solar flux modifier 22 includes four panels 26 that extend from the lower wall 24 and converge toward each other. The solar flux modifier 22 also includes reflective surfaces 28 on the inwardly facing sides of the panels 26, for directing light onto the cells.

The receiver 14 includes a dense array of 2304 closely packed rectangular photovoltaic cells which are mounted to 64 square modules 30. In the example, each module 30 includes 36 photovoltaic cells arranged in a 6 cell by 6 cell array. The photovoltaic cells are mounted on each module 30 so that the photon source facing surface of the cell array is a mostly continuous surface. The modules 30 are mounted to the lower wall 24 of the box-like structure of the receiver 14 so that, in this example, the exposed photon source facing surface of the combined array of photovoltaic cells is in a single plane.

Each module 30 includes a coolant flow path. The coolant flow path is an integrated part of each module 30 and allows coolant to be in thermal contact with the photovoltaic cells and extract heat from the cells. The coolant flow path of the modules 30 forms part of the coolant circuit. The coolant circuit also includes channels 32 on the flux modifier 22.

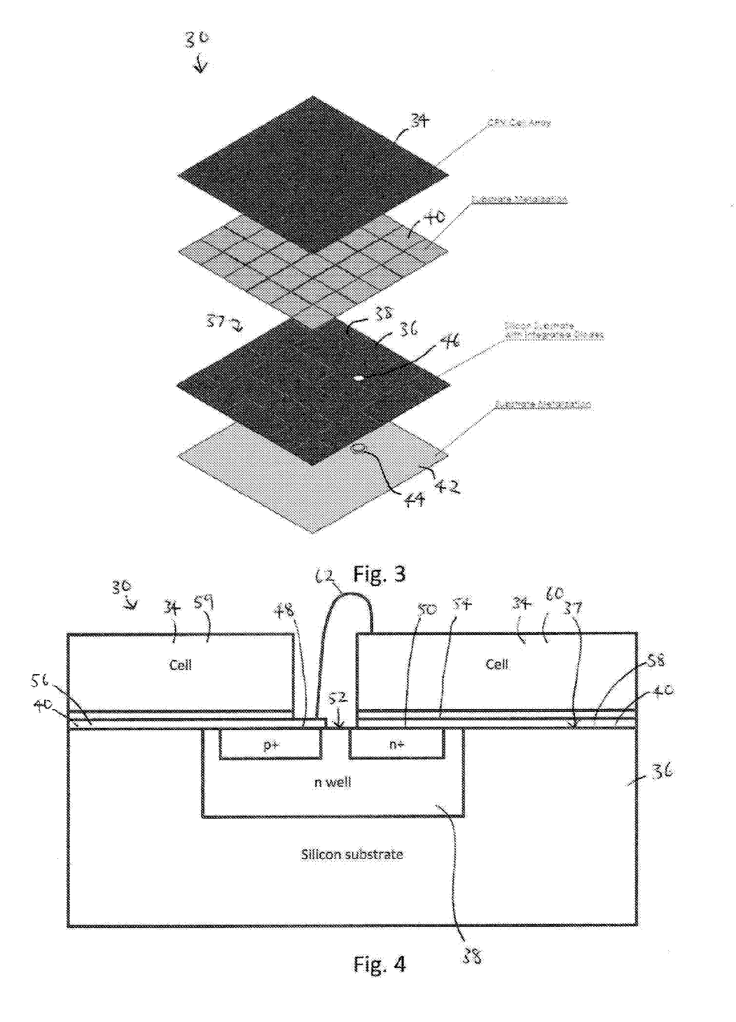

With reference to FIG. 3, each module 30 includes a dense array of photovoltaic cells 34 and a semiconductor substrate 36 including bypass diodes 38 formed integrally in the semiconductor substrate 36. In this example, the photovoltaic cells 34 are multijunction cells, the substrate is a silicon substrate and each bypass diode 38 corresponds to a respective one of the photovoltaic cells 34, for conducting current if the respective cell 34 is shaded or damaged. The substrate 36 includes a cell side surface 37 that is substantially planar.

The substrate has a thickness of 0.1 to 1 mm, for example 0.2 mm, and the bypass diodes have a thickness in the order of 5 um and dimensions roughly equal to the photovoltaic cells in width and about 50 ums in length (along the direction of current flow).

The module 30 also includes metallised zones 40 provided between the substrate 36 and the photovoltaic cells 34, the metallised zones 40 being electrically and thermally coupled to the photovoltaic cells 34 and the bypass diodes 38 when the module 30 is assembled. The metallised zones 40 are rectangular and arranged in an array with a grid of gaps between the metallised zones 40. The metallised zones may be made of, for example, gold, copper, aluminium or silver and may have a thickness of around 5 um. The gaps between the metallised zones may be about 10 um.

A substrate metallisation layer 42 may also be provided below the substrate 36. This is for bonding a separate heatsink to the substrate, which could be bonded by solder or possibly conductive adhesive. Alternatively, the heat sink may be formed integrally in the semiconductor substrate. The substrate metallisation layer 42 and substrate 36 both include holes 44 and 46 respectively through which a power pin may be inserted, to make electrical contact with an end photovoltaic cell 34 in the series. A second power pin may be connected to make electrical contact with the other end photovoltaic cell 34 in the series. Alternatively, through silicon vias (TSVs) may be used to take power to the rear surface.

As shown in FIG. 4, each bypass diode 38 includes a first terminal 48 and a second terminal 50, the first and second terminals 48, 50 being located on the cell side surface 37 of the semiconductor substrate 36. A junction 52 on the cell side surface 37 between the first terminal 48 and second terminal 50 is located between two photovoltaic cells 34. This junction 52 on the surface 37 is one edge of the PN junction between the P and N type regions of the diode 38.

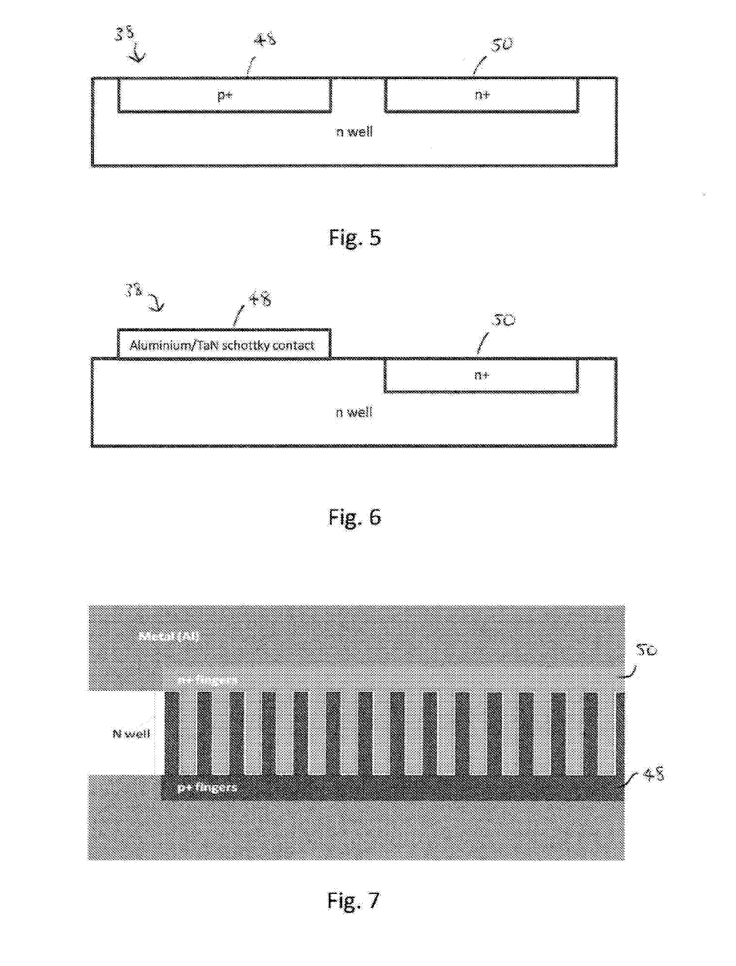

Two types of bypass diodes that may be used are shown in FIGS. 5 and 6. In FIG. 5, the bypass diode 38 is a PN diode, including a positive terminal 48 and a negative terminal 50. The PN diode 38 is formed by creating an n well in a semiconductor substrate 36 using diffusion or ion implantation, then doping an N-type region (for example with phosphorous or arsenic) and a P-type region (for example with boron or aluminium). The n well provides junction isolation between the diode and the semiconductor substrate, which is typically p type. This assists to prevent current flowing through the substrate.

In FIG. 6, the bypass diode 38 is a schottky diode, including a positive aluminium/tantalum nitride (Al/TaN) schottky positive contact 48 and a negative terminal 50. The schottky diode is formed using similar processes to the PN diode, except that instead of doping a P-type region, the aluminium/tantalum nitride is deposited onto the n well.

An interleaved or finger shaped bypass diode design that may be used is shown in FIG. 7. In this example, the positive terminal 48 and negative terminal 50 are shaped as interleaved combs. This design increases the contact area between the P and N regions and thus allows a greater current to flow across the junction.

The metallised zones 40 are provided between the photovoltaic cells 34 and the bypass diodes 38 to complete the circuit, placing the cells 34 in series with each other, and the bypass diodes 38 in parallel across the cells 34. The metallised zones 40 are deposited on the substrate 36 using vapour deposition, ion-beam sputtering or other thin film techniques. For example, the metallised zones 40 may be formed by patterning on a mask of photoresist, metallising and then lifting off the photoresist. In another example, the wafer may be coated with metal and then etched around the zones 40. The photovoltaic cells 34 are then mounted to their respective metallised zone 40 by depositing solder 54 on the metallised zone 40 and using a pick and place robot to place the cell 34 on the solder 54.

As illustrated in FIG. 4, when the module 30 is assembled a first metallised zone 56 at least partially overlies the first terminal 48 of the bypass diode 38 and at least partially underlies a first photovoltaic cell 59. The first metallised zone 56 is adjacent to a bottom terminal of the first cell 59. A second metallised zone 58 at least partially overlies the second terminal 50 of the diode 38 and at least partially underlies a second photovoltaic cell 60. The second metallised zone 58 is adjacent to a bottom terminal of the second cell 60. A top terminal (e.g. busbar) of the second cell 60 is connected to the bottom terminal of the first cell 59 via a wire bond 62. The wire bond 62 also connects the bypass diode 38 in parallel to cell 60, with the bypass diode 38 having a polarity opposite to the polarity of the cell 60.

Thus, each metallised zone 40 (apart from the end photovoltaic cells in the series) underlies a photovoltaic cell 34 and connects the photovoltaic cell 34 to a first terminal of a bypass diode 38 corresponding to the photovoltaic cell and to the second terminal of a bypass diode corresponding to an adjacent photovoltaic cell. The end photovoltaic cells 34 are connected only to a single terminal of a bypass diode 38, and are also connected to a power pin.

The surface area of each metallised zone 40 in this embodiment is slightly larger than the footprint of a cell 34. Parts of the metallised zone 40 extending outside of the footprint of the cell 34 are used to connect the wire bonds 62. There may be multiple wire bonds per cell, for example forty wirebonds. In alternate embodiments, each metallised zone 40 may have a smaller surface area than the footprint of a cell 34. However, larger metallised zones are preferred, to facilitate heat transfer from the cell to the substrate.

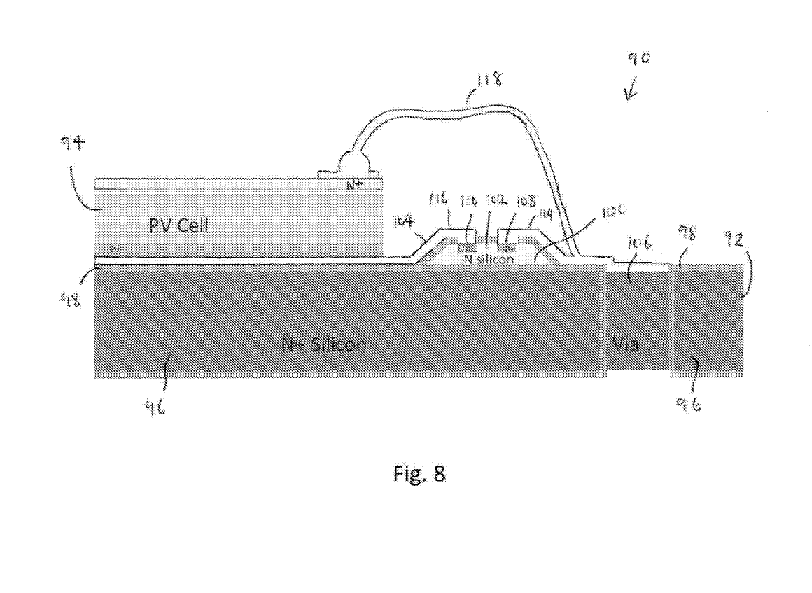

A photovoltaic power module 90 according to another embodiment of the invention is shown in FIG. 8. The module 90 includes a silicon on insulator (SOI) substrate 92 and a dense array of photovoltaic cells. Only one PV cell 94 is shown for illustrative purposes. The SOI substrate 92 includes a bottom silicon layer 96, an insulating silicon dioxide layer 98 and a top silicon layer 100. Bypass diodes are integrated into the top silicon layer 100 of the SOI substrate 92. Only one bypass diode 102 is shown in FIG. 8 for illustrative purposes.

The module 90 also includes metallised zones 104 provided between the SOI substrate 92 and the photovoltaic cells 94. The metallised zones 104 are electrically and thermally coupled to the photovoltaic cells 94 and the bypass diodes 102. The cell 94 in this example is a final cell in a string of series connected cells in the module 90. A through silicon via (TSV) 106 formed in the SOI substrate 92 connects the cell 94 to a back surface of the module 90.

The bypass diode 102 includes a first terminal 108 and a second terminal 110, and is formed in the top silicon layer 100 by creating an n well in the SOI substrate 92 and then doping an N-type region and a P-type region, according to the steps described above in relation to the conventional silicon substrate embodiment. The SOI substrate embodiment allows a larger voltage across the photovoltaic cells 94 in a smaller space when compared to the conventional silicon wafer substrate embodiment, as the insulating layer 98 provides greater insulation than the junction isolation provided by the n well.

The metallised zones 104 are deposited on the SOI substrate 92 with integrated bypass diodes 102 using techniques as described above. A first metallised zone 114 overlies the first terminal 108 of the bypass diode 102 and connects the circuit to the TSV 106. A second metallised zone 116 overlies the second terminal 110 of the bypass diode 102 and underlies the photovoltaic cell 94. A top terminal of the cell 94 is connected to the second metallised zone 116 (and thus to the TSV 106) by a wire bond 118. The wire bond 118 and second metallised zone 116 also connects the bypass diode 102 in parallel with the photovoltaic cell 94, with the bypass diode 102 having a polarity opposite to the polarity of the cell 94.

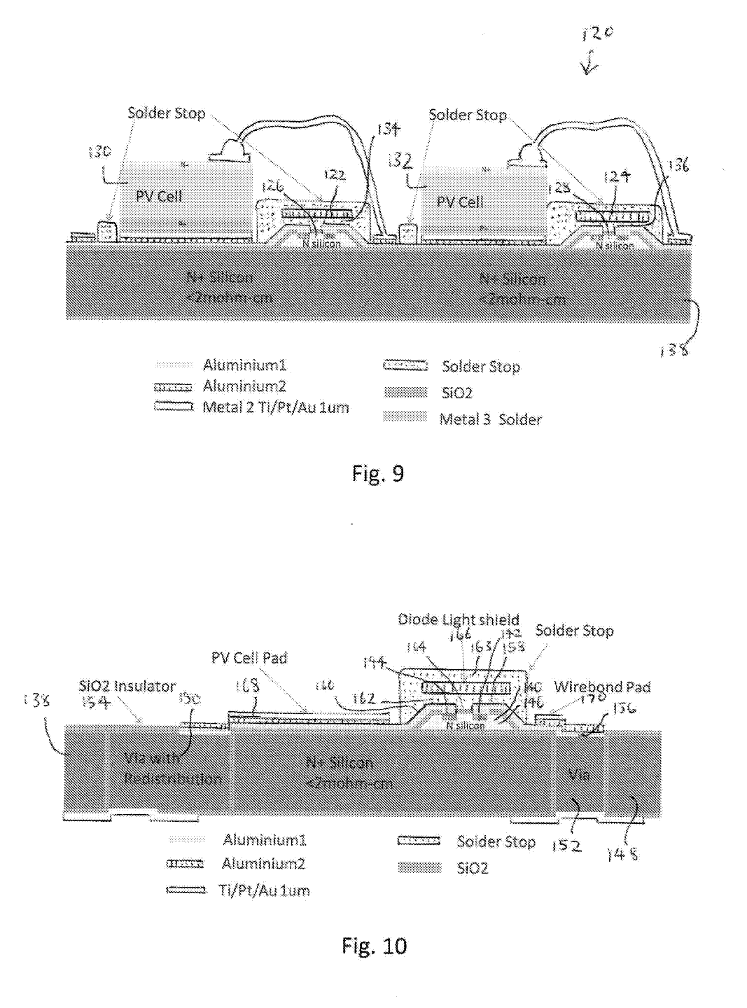

A photovoltaic power module 120 according to yet another embodiment of the invention is shown in FIG. 9. The photovoltaic power module 120 is similar to the photovoltaic power module 90 shown in FIG. 8, except that the module 120 also includes shields 122, 124 associated with bypass diodes 126, 128 respectively. The shields 122, 124 reduce exposure of the bypass diodes 126, 128 to photons, thus preventing the diodes 126, 128 from becoming exposed to concentrated sunlight and shunting current through the photovoltaic cells 130, 132.

The shields 122, 124 in this embodiment are made of aluminium, although any other suitable metal could be used. The aluminium is opaque and reflects light away from the diodes. A dielectric material 134, 136 between the shields 122, 124 and associated bypass diodes 126, 128 prevents the metal shields 122, 124 from shorting the bypass diodes 126, 128. As in FIG. 8, the bypass diodes 126, 128 are formed integrally in a silicon on insulator (SOI) substrate 138.

A method of manufacturing the semiconductor substrate 138 will be described with reference to FIG. 10. FIG. 10 shows a position on the substrate 138 for locating an end photovoltaic cell in a series of connected photovoltaic cells.

The method includes highly doping a bottom silicon layer 148 so that it becomes a very conductive N+ substrate. In this example, the bottom silicon layer 148 is doped to less than 2 mohm-cm, e.g. 0.001 ohm-cm. Through-silicon vias 150, 152 are created by etching channels in the bottom silicon layer 148 and coating the channels with an insulator, such as silicon dioxide. For example, four channels forming a rectangle may define one via through the substrate. The highly doped semiconductor material of the bottom silicon layer 148 that is between the channels defining the via 150 or 152 enables current to flow from photovoltaic cells to power pins on a back of the semiconductor substrate 138. The power pins may be located at any position on the back of the substrate 138, and the channels may be defined to ensure current flow to that position from the appropriate photovoltaic cell.

At the same time as etching the channels forming the vias 150, 152, one or more channels may be etched around the edge of the substrate 138 and filled with an insulator, such as silicon dioxide, to allow a high stand off voltage across the substrate.

An insulating layer 154 formed from silicon dioxide is deposited over the bottom silicon layer 148, and then a top silicon layer 146 is deposited. The top silicon layer 146 is doped to form a bypass diode 140 integrally in the substrate 138. The bypass diode 140 includes a first terminal 142 and a second terminal 144, and is formed in a top silicon layer 146 of the SOI substrate 138 by creating an n well then doping an N-type region and a P-type region, as described above.

Metallised zones 156 are deposited on the SOI substrate 138 using techniques as described above. A first metallised zone 158 overlies the first terminal 142 of the bypass diode 140 and connects the circuit to the via 152. A second metallised zone 160 overlies the second terminal 144 of the bypass diode 140 and connects the circuit to the other via 150. The metallised zones 156 in this embodiment are composed of aluminium.

A dielectric solder stop layer 162 is then deposited to overlie the bypass diode 140 and sections of the metallised zones 156 which are positioned above the bypass diode 140. The dielectric may also be deposited over a position on the substrate 138, between the intended locations for a photovoltaic cell and a wirebond connecting an adjacent photovoltaic cell to the substrate, as shown in FIG. 9. This may assist in preventing unwanted electrical conductivity between cells when soldered onto the substrate. The dielectric layer 162 may be, for example, a 1 micron layer of silicon dioxide or silicon nitride, or a 5 micron polymer layer, such as BCB. It may be deposited using a plasma assisted process.

After depositing the dielectric material, a further metallised zone or shield 166 is deposited to overlie the bypass diode 140. FIG. 10 shows only one metallised zone 166, but it will be appreciated that this technique can be applied to other bypass diodes in the substrate 138. The metallised zone 166 preferably overlies at least the first terminal 142, the second terminal 144 and the junction 164 between the first terminal 142 and second terminal 144 to reduce exposure of the bypass diode 140 to photons. It is preferred to cover an area larger than the bypass diode 140 with the metallised zone 166 to minimise light under the metallised zone 166. The metallised zone 166 in this embodiment is a 1 micron thick layer of aluminium. At the time of depositing the metallised zone 166, further metallised zones may be deposited on top of the previously deposited metallised zones 156, as shown in FIG. 10.

As an optional step, further dielectric material 163 may be deposited to at least overlie the further metallised zone 166. Dielectric material may thus encapsulate the metallised zone 166, preventing the metal from shorting any of the surrounding components of the photovoltaic power module.

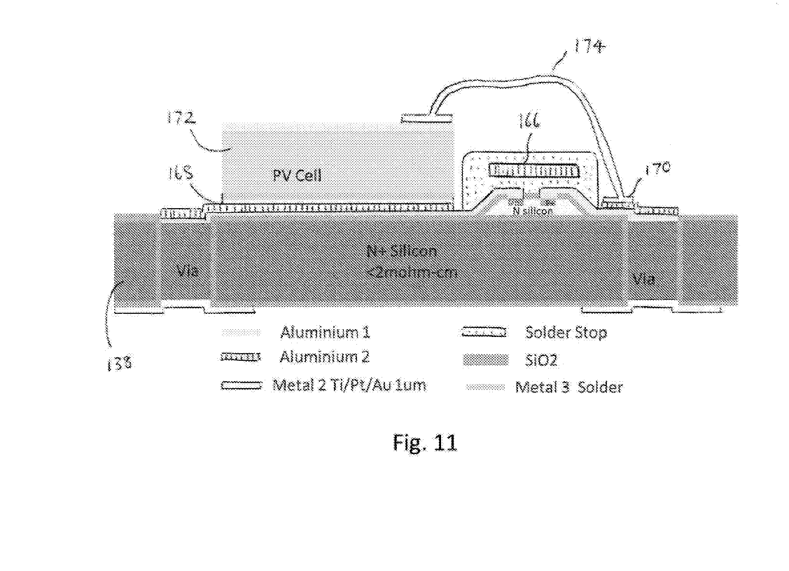

Finally, solder wettable zones including PV cell pad 168 and wirebond pad 170 are deposited onto the substrate 138, to enable a photovoltaic cell and a wirebond to be soldered to the substrate. The solder wettable zones 168, 170 may be made of copper, platinum, gold or any other solder wettable material. FIG. 11 shows a photovoltaic cell 172 soldered to the solder wettable PV cell pad 168. The photovoltaic cell 172 is wirebonded 174 to the solder wettable wirebond pad 170 to connect it into the circuit. The wirebond 174 may also be made of copper, platinum or gold. Further metallised zones, made of solder wettable material, may be deposited underneath the substrate, for attachment of power pins.

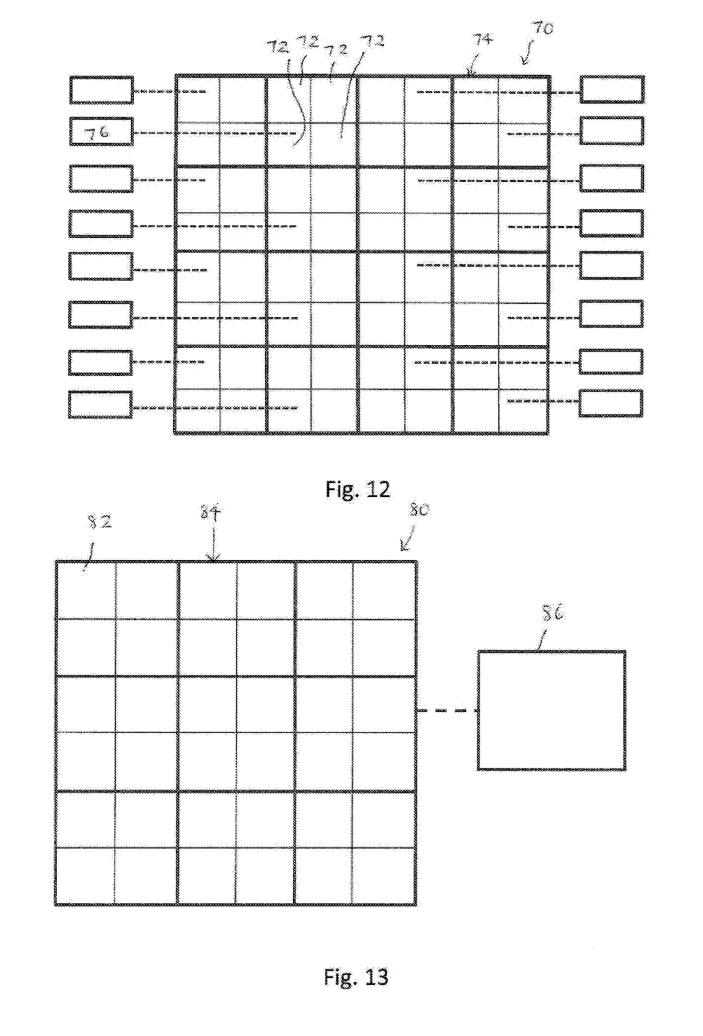

FIG. 12 shows an another embodiment of a photovoltaic power module 70, which includes an array of 8×8 photovoltaic cells 72 and a semiconductor substrate 74 including power converters (shown schematically as 76) formed integrally in the semiconductor substrate. Each power converter 76 in this embodiment corresponds to a group of 4 series connected cells 72 located in a 2×2 array. The 2×2 arrays are shown by the bold grid lines in the diagram.

FIG. 13 shows yet another embodiment of a photovoltaic power module 80, which this time includes an array of 6×6 photovoltaic cells 82 and a semiconductor substrate 84 including a single power converter (shown schematically as 86). The power converters 76 and 86 may each be an inverter, a DC-DC converter or a DC-DC converter connected to an inverter.

For example, where the power converter is an inverter without a DC-DC converter, all PV cells may be connected in series to achieve higher voltage to match the inverter requirement. The power output may, however, be subject to uniformity of flux distribution on the module area. The power output is limited by the weakest PV cell. Also, a transformer may be required to step up the AC output of the inverter.

In another example, where the power converter is a DC-DC-converter, all PV cells may be connected in parallel. This may minimise uneven flux distribution impact on the PV module power generation. The DC-DC converter may be connected to an inverter, which is also incorporated into the silicon substrate, or which may be separate from the substrate.

The DC-DC converter and/or inverter may be incorporated into the silicon substrate design by forming MOSFETs, IGBTs, resistors, capacitors, inductors, logic gates, control circuits and other components in the substrate using semiconductor wafer processing techniques. These components may be formed on the back of the module, underneath the heat sink. The power converter may be connected to the cells by through silicon vias, or a wirebond extending around the outside of the substrate.

Other components may also be incorporated into the substrate, for example, monitoring circuits, temperature sensors, current sensors and/or blocking diodes. These components may be formed on an edge of the substrate, on a separate silicon layer underneath the substrate, under an integrally formed heatsink, or between the substrate and heatsink, all integrally formed.

It is to be understood that various alterations, additions and/or modifications may be made to the parts previously described without departing from the ambit of the present invention, and that, in the light of the above teachings, the present invention may be implemented in a variety of manners as would be understood by the skilled person.

1. A photovoltaic power module including
one or more photovoltaic cells for converting photons to electrical energy,
a semiconductor substrate including one or more bypass diodes formed integrally in the semiconductor substrate, each bypass diode corresponding to a respective one or more of the photovoltaic cells, and
metallised zones constituting a circuit and provided between the substrate and the photovoltaic cells, the metallised zones being electrically and thermally coupled to the photovoltaic cells and the bypass diodes.

2. A photovoltaic power module as claimed in claim 1,
wherein the semiconductor substrate includes a cell side surface, wherein each bypass diode includes a first terminal and a second terminal, the first and second terminals being located on the cell side surface of the semiconductor substrate.

3. A photovoltaic power module as claimed in claim 2, wherein for each bypass diode, a first metallised zone at least partially overlies the first terminal and at least partially underlies a first photovoltaic cell of the one or more photovoltaic cells and a second metallised zone at least partially overlies the second terminal and at least partially underlies a second photovoltaic cell of the one or more photovoltaic cells.

4. A photovoltaic power module as claimed in claim 1, further including a shield associated with each bypass diode for reducing exposure of the bypass diode to photons.

5. A photovoltaic power module as claimed in claim 4, wherein each shield is opaque.

6. A photovoltaic power module as claimed in claim 5, wherein each shield is made of metal, further including a dielectric material between each shield and its associated bypass diode.

7. A photovoltaic power module as claimed in claim 2, wherein the photovoltaic cells are connected in series and each photovoltaic cell apart from end photovoltaic cells in the series has an associated metallised zone that underlies the photovoltaic cell and connects the photovoltaic cell to a first terminal of a bypass diode corresponding to the photovoltaic cell and to the second terminal of a bypass diode corresponding to an adjacent photovoltaic cell.

8. A photovoltaic power module as claimed in claim 1, wherein the semiconductor substrate is a silicon on insulator substrate.

9. A photovoltaic power module as claimed in claim 8, wherein a bottom silicon layer of the silicon on insulator substrate is highly doped.

10. A photovoltaic power module as claimed in claim 9, further including vias in the bottom silicon layer connecting end photovoltaic cells in a series of connected photovoltaic cells to power pins on a back of the photovoltaic power module.

11. A photovoltaic power module as claimed in claim 1, wherein the semiconductor substrate further includes a heat sink formed integrally in the semiconductor substrate.

12. A photovoltaic power module as claimed in claim 1, wherein the one or more photovoltaic cells are multijunction photovoltaic cells.

13. A photovoltaic power module as claimed in claim 1, wherein the semiconductor substrate further includes one or more power converters formed integrally in the semiconductor substrate.

14. A photovoltaic power module as claimed in claim 1, wherein the semiconductor substrate further includes, for each photovoltaic cell, a power converter formed integrally in the semiconductor substrate.

15. A photovoltaic power module as claimed in claim 1, wherein the semiconductor substrate further includes, for one or more groups of series connected photovoltaic cells, a power converter formed integrally in the semiconductor substrate, wherein each group of series connected photovoltaic cells is located in an n×n array.

16. A photovoltaic power module as claimed in claim 14, wherein the power converter is an inverter, a DC-DC converter or a DC-DC converter connected to an inverter.

17. A semiconductor substrate including one or more bypass diodes formed integrally in the semiconductor substrate, each bypass diode corresponding to a respective one or more photovoltaic cells, and metallised zones being electrically and thermally coupled to the bypass diodes.

18. A semiconductor substrate as claimed in claim 17, wherein the semiconductor substrate includes a cell side surface, wherein each bypass diode includes a first terminal and a second terminal, the first and second terminals being located on the cell side surface of the semiconductor substrate.

19. A semiconductor substrate as claimed in claim 18, wherein for each bypass diode, a first metallised zone at least partially overlies the first terminal and a second metallised zone at least partially overlies the second terminal.

20. A semiconductor substrate as claimed in claim 17, further including a shield associated with each bypass diode for reducing exposure of the bypass diode to photons.

21. A semiconductor substrate as claimed in claim 20, wherein each shield is opaque.

22. A semiconductor substrate as claimed in claim 21, wherein each shield is made of metal, further including a dielectric material between each shield and its associated bypass diode.

23. A semiconductor substrate as claimed in claim 17, wherein the semiconductor substrate is a silicon on insulator substrate.

24. A semiconductor substrate as claimed in claim 23, wherein a bottom silicon layer of the silicon on insulator substrate is highly doped.

25. A semiconductor substrate as claimed in claim 24, further including vias in the bottom silicon layer to connect end photovoltaic cells in a series of connected photovoltaic cells to power pins on a back of the semiconductor substrate.

26. A semiconductor substrate as claimed in claim 17, further including a heat sink formed integrally in the semiconductor substrate.

27. A semiconductor substrate as claimed in claim 17, further including one or more power converters formed integrally in the semiconductor substrate.

28. A semiconductor substrate as claimed in claim 27, wherein the power converter is an inverter, a DC-DC converter or a DC-DC converter connected to an inverter.

29. A method of manufacturing a photovoltaic power module including
doping a semiconductor substrate to form one or more bypass diodes integrally in the semiconductor substrate, the semiconductor substrate including a cell side surface, wherein each bypass diode includes a first terminal and a second terminal, the first and second terminals being located on the cell side surface of the semiconductor substrate,
depositing metallised zones to at least partially overlie a first terminal of a bypass diode and a second terminal of an adjacent bypass diode, and
mounting one or more photovoltaic cells in electrical connection with the metallised zones.

30. A method as claimed in claim 29, further including
after depositing the metallised zones, depositing a dielectric material to at least partially overlie each bypass diode, and
depositing further metallised zones over the dielectric material, thus reducing exposure of the bypass diodes to photons.

31. A method as claimed in claim 30, further including
after depositing the further metallised zones, depositing further dielectric material over the further metallised zones.

32. A method as claimed in claim 29, wherein the semiconductor substrate is a silicon on insulator substrate, further including
highly doping a bottom silicon layer of the silicon on insulator substrate.

33. A method as claimed in claim 32, further including
etching channels to form vias in the bottom silicon layer, the vias connecting end photovoltaic cells in a series of connected photovoltaic cells to power pins on a back of the photovoltaic power module, and
coating the channels with an insulator.

34. A method as claimed in claim 29, further including
stacking and etching semiconductor wafers to form a heat sink integrally in the semiconductor substrate.

35. A method of manufacturing a semiconductor substrate including
doping a semiconductor substrate to form one or more bypass diodes integrally in the semiconductor substrate, the semiconductor substrate including a cell side surface, wherein each bypass diode includes a first terminal and a second terminal, the first and second terminals being located on the cell side surface of the semiconductor substrate, and
depositing metallised zones to at least partially overlie a first terminal of a bypass diode and a second terminal of an adjacent bypass diode.

36. A method as claimed in claim 35, further including
after depositing the metallised zones, depositing a dielectric material to at least partially overlie each bypass diode, and
depositing further metallised zones over the dielectric material, thus reducing exposure of the bypass diodes to photons.

37. A method as claimed in claim 35, wherein the semiconductor substrate is a silicon on insulator substrate, further including
highly doping a bottom silicon layer of the silicon on insulator substrate,
etching channels to form vias in the bottom silicon layer, and
coating the channels with an insulator.

38. A photovoltaic power module including one or more photovoltaic cells for converting photons to electrical energy and a semiconductor substrate including one or more power converters formed integrally in the semiconductor substrate, each power converter corresponding to a respective one or more of the photovoltaic cells.
